(19) United States
(12) Patent Application Publication
(10) Pub. No.: US 2004/0095184 A1
(43) Pub. Date: May 20, 2004

(54) Driving circuit and driving method of light emitting device and optical communication apparatus

(75) Inventors: Hiroyuki Oka, Tokyo (JP); Yoshiki Furukawa, Tokyo (JP)

Correspondence Address: William Squire, Esq., Carella, Byrne, Bain, Gilfillan, Cecchi,, Stewart & Olstein, 6 Becker Farm Road, Roseland, NJ, 07068-1739, US

(73) Assignee: Stanley Electric Co., Ltd.

(21) Appl. No.: 10/697,235

(22) Filed: Oct. 30, 2003

(30) Foreign Application Priority Data
Nov. 20, 2002 (JP) 2002-336623
Apr. 10, 2003 (JP) 2003-106969

(51) Int. Cl. H03K 17/60

(52) U.S. Cl. 327/478

(57) ABSTRACT

A driving circuit for a light emitting device keeping its excellent eye pattern by improving an extinction ratio and reducing power consumption, can be provided by arranging the following way. The driving circuit has a driving unit having a frequency response curve indicating opposite property to a frequency response curve of the light emitting device. The driving unit comprises a power outputting type amplifier constituted by a transistor having a gain curve increasing with a predetermined gradient starting from a cut-off frequency of the light emitting device. The amplifier comprises a frequency generating unit constituted by a capacitor and a resistance for generating a desired frequency, a current multiplier unit constituted by a current mirror circuit comprising 7 transistors and a discharge circuit for applying a reverse current, which is distributed from the current multiplier circuit, to the light emitting device.

### BACKGROUND OF THE INVENTION

1. Field of the Invention

The present invention relates to a driving circuit and a driving method of a light emitting device such as an LED or a laser diode, which converts an electric current into light, and relates to an optical communication apparatus. The present invention particularly relates to a driving circuit and a driving method capable of being applied to a fast communication system.

2. Brief Description of the Related Art

Since a light emitting diode (hereinafter referred as “LED”) as a light emitting device can be handled without difficulties and be obtained at an inexpensive price, it is applied to various optical communication usage including remote control units for electric appliances. However, due to a limited response time of the LED, it is difficult to apply the LED to recent fast communication systems such as the latest general purpose interface stipulated by IEEE1394 standard having a transfer rate of 400 Mbps.

FIG. 6 is a circuit diagram showing a driving circuit for a conventional light emitting device as an example of fast LED driving circuits used for optical communication. In FIG. 6, a reference character “Q11” is a logic driver IC, which outputs serial data to be transmitted as “high” logic voltage levels or “low” logic voltage levels.

In order to obtain a sufficient optical power from an LED 11, a driver IC with a high current power is employed as the logic driver IC Q11. For example a standard CMOS logic IC 74AC04 is employed. An output amplitude gained by the CMOS logic IC 74AC04 is nearly equal to a power voltage for this IC. This logic IC can be driven by a high driving current at a high driving rate up to a maximum of 100 Mbps. Sometimes, a plurality of drivers are connected in parallel for enhancing the current capability.

Reference characters “R11” and “R12” in the drawing are resistances for limiting a current flowing out of the LED 11 during a light emitting period. In other words, a driving voltage Vcc is converted to the current by these resistances R11 and R12. A reference numeral “12” is a power source having a voltage of Vcc.

A reference character “C11” is a capacitor, and it is also called as a speed-up capacitor. A current flowing in the capacitor C11 at a time when light emission is initiated, is added to the driving current as a differential current of the original driving current so that a fast initiating step of the light emission by the LED 11 is accelerated. When the light emission is stopped, accumulated electric charge is added to the high logic voltage, which is applied to the LED 11 as a reverse bias voltage so as to discharge electric charge in the LED rapidly.

A reference character “R13” is a resistance to which a predetermined bias current is flowed even during an extinction period of the LED so that a starting period of the light emission is shortened. The above-described example of the driving circuits has a simple constitution, but it is a highly practical circuit such that fast optical signals can be obtained.

FIG. 7 shows another example of the conventional driving circuits for the light emitting devices. In the drawing, reference characters “Q12” and “Q13” are transistors constituting a differential circuit. A resistance R14 is connected to the transistor Q12 and a bias voltage Vbias from a direct current voltage source 14 is applied to a base of the transistor Q13 connected to the LED 11. An accumulated current from the transistors Q12 and Q13 is determined by a constant current source 15.

In this example since the transistors Q12 and Q13 are designed not to be used in saturation/cut-off regions, it is possible to drive the light emitting device rapidly. In stead of the bias voltage applied to the base of the transistor Q13, the transistor Q13 may be driven by signals with a reverse phase to inputted signals to the transistor Q12.

Further, the following ways to obtain fast optical signals by utilizing the LED are proposed.

(1) A bias current or voltage is applied to the LED beforehand so as to reduce a delayed time before the light emission driven by a signal driving current. (See, for example, Japanese laid open patent Nos. 2001-326569, 2000-232240, 2000-228543, 5-29655, 63-77172 and 60-180232.)

(2) A differential component of an inputted signal is added to the signal driving current in order to emphasize a change of the current so as to raise a driving rate. (See, for example, Japanese laid open patent Nos. 2000-232240, 2000-299498, 11-74567, 11-40855, 10-242522, 10-65217, 9-148631, 7-122783, 5-121783, 5-90642, 3-27579, 2-272778 and 58-137340.)

(3) Electric charge is sucked from outside when the LED is switched off. (See, for example, Japanese laid open patent Nos. 2000-101047, 5-7144, 1-138766 and 64-5078.)

However, conventional driving circuits disclosed in the above-referred patents have the following problems.

With regard to the methods mentioned in (2) (referred as a “peaking method”), it is difficult to determine a time constant (for example a constant determined by values of R12 and C11 in FIG. 6). It is supposed that a reason for such difficulty is based on ideas to improve transient changes by controlling emission /extinction of the LED, namely, by controlling on/off operations of the LED. In other words, since the differential current should be added by keeping the original driving voltage (a voltage level after a transient period by the peaking method), it is difficult to determine a proper time constant. Because the time constant is restricted by a power source voltage, and by an operating rate and a performance of the driving circuit.

Since a response time (a transient time after started or a transient time after stopped) of the standard logic drive IC in the circuit shown in FIG. 6 is around 5 ns, an attainable rate would be at most 100 Mbps (1 bit=10 ns).

However a higher rate can be attained, when the driving circuit is modified into a driving circuit shown in FIG. 7. If transistors (including FET) in the logic driver IC shown in FIG. 6 operated up to in saturation/cut-off regions, are adjusted such that they are operated only in active regions, it is possible to attain a faster operating rate.

However, since the driving circuit for driving the LED shown in FIG. 7 requires a current power source with two times capacity than that of the driving circuit shown in FIG. 6, more power is consumed by the driving circuit.

### SUMMARY OF THE INVENTION

Embodiment 1 by the present invention is carried out in view of solving the above-mentioned problems so as to provide a driving circuit and driving method of a light emitting device, and an optical communication system with a simple arrangement capable of reducing power consumption and obtaining optical signals with higher frequency components than a cut-off frequency of the light emitting device.

The driving circuit for a light emitting device has a driving unit having a frequency response curve indicating opposite property to a frequency response curve of the light emitting device.

The above-mentioned driving unit comprises a power outputting type amplifier having a gain curve increasing with a gradient of ca. 6 dB/oct starting from a cut-off frequency of the light emitting device. And the amplifier comprises a frequency generating unit for generating a desired frequency and a current multiplier unit constituted by a current mirror circuit.

A driving method for driving a light emitting device by the present invention is arranged such that the light emitting device is driven by a driving unit having a frequency response curve indicating opposite property to a frequency response curve of the light emitting device. The driving unit comprises a power outputting type amplifier having a gain curve increasing with a gradient of ca. 6 dB/oct starting from a cut-off frequency of the light emitting device.

Further the present invention provides more enhanced driving circuits, driving methods and optical communication apparatuses capable of having higher frequency responses by keeping power consumption at a level as in embodiment 1.

The driving circuit for the light emitting device has a driving unit having a frequency response curve indicating opposite property to a frequency response curve of the light emitting device. The driving unit comprises a power outputting type amplifier having a gain curve increasing with a predetermined gradient starting from a cut-off frequency of the light emitting device. The amplifier comprises: a frequency generating unit for generating a desired frequency; a current multiplier unit constituted by a current mirror circuit; and a discharge circuit for applying a reverse current distributed from the current multiplier circuit to the light emitting device.

The driving method for the light emitting device is arranged such that the light emitting device is driven by a driving unit. The driving unit comprises a frequency generating unit having a frequency response curve indicating opposite property to a frequency response curve of the light emitting device and having a gain curve increasing with a predetermined gradient starting from a cut-off frequency of the light emitting device, and a power outputting type amplifier having a current multiplier unit constituted by a current mirror circuit. A reverse current distributed from the current multiplier unit is applied to the light emitting device by a discharge circuit.

An optical communication apparatus by the present invention is equipped with one of the above-mentioned driving circuits for the light emitting device.

### BRIEF DESCRIPTION OF THE DRAWINGS

FIG. 1 is a block diagram illustrating a rough constitution of embodiment 1 by the present invention.

FIG. 2 is a chart showing a relation between frequencies of inputted signals and outputs gained by the LED.

FIG. 3 is a chart showing a relation between frequencies of inputted signals and outputs gained by an amplifier.

FIG. 4 is a chart showing a relation between frequencies of inputted signals and outputs gained by embodiment 1.

FIG. 5 is a circuit diagram showing a constitution of the driving circuit for the LED by embodiment 1.

FIG. 6 is the circuit diagram showing the constitution of the conventional driving circuit for the LED.

FIG. 7 is the circuit diagram showing the constitution of the another conventional driving circuit for the LED.

FIG. 8 is a circuit diagram showing a constitution of a driving circuit for the LED by embodiment 2.

FIG. 9 is a chart showing a relation between frequencies of inputted signals and outputs gained by embodiment 2 when the LED is on.

FIG. 10 is a chart showing a relation between frequencies of inputted signals outputs gained by embodiment 2 when the LED is off.

FIG. 11 is charts showing gains of various portions the driving circuit by embodiment 2 in relation to elapsed time.

FIG. 12 is a chart showing a light emitting eye pattern gained by embodiment 2.

FIG. 13 is a circuit diagram showing a constitution of a driving circuit for the LED by embodiment 3.

FIG. 14 is a circuit diagram showing a constitution of a driving circuit for the LED by embodiment 4.

FIG. 15 is a chart showing a light emitting eye pattern by embodiment 1.

FIG. 16 is a chart showing a driving current waveform by embodiment 1.

FIG. 17 is a chart showing a light emitting eye pattern when an extinction ratio is raised.

FIG. 18 is a chart showing a driving current waveform when an extinction ratio is raised.

### DETAILED DESCRIPTION OF THE PREFERRED EMBODIMENTS

Hereinafter embodiments by the present invention are explained as referring to the drawings.

### Embodiment 1

The present embodiment is characterized that the light emitting device is driven by an amplifier having a reverse gain property to a gain property of the light emitting device. Here an LED is employed as the light emitting device and is driven by an equalizing amplifier so as to equalize gained outputs of the LED.

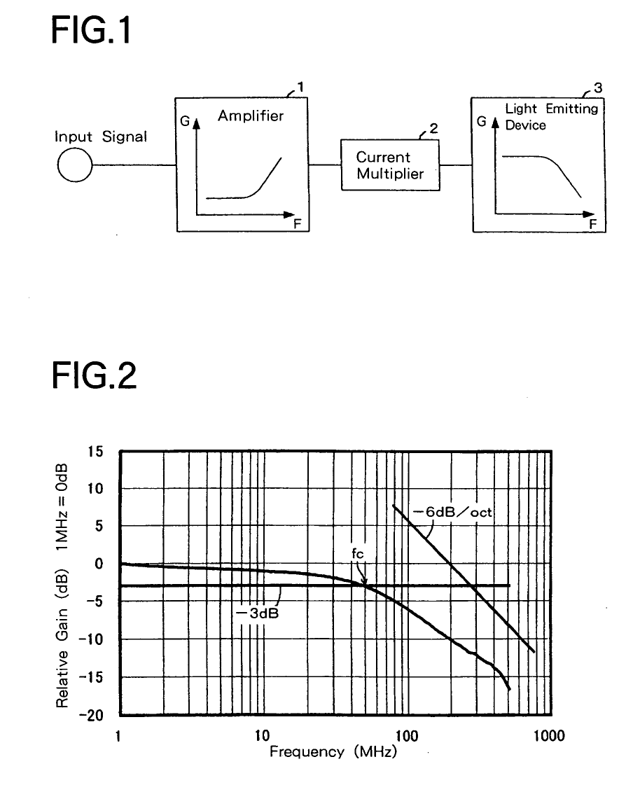

FIG. 1 is the block diagram showing the constitution of the present embodiment, which shows a fundamental constitution of a driving circuit for the LED arranged in an optical communication apparatus. The driving circuit is arranged such that a driving unit constituted by an amplifier 1 and a current multiplier circuit 2, has a reverse gain property to a gain property of an LED (light emitting diode) 3 in relation to frequencies of inputted signals.

The above-mentioned driving unit is constituted by a power output type amplifier having a gain property with a gradient of ca. 6 dB/oct incrementing from a cutoff frequency of the LED 3. Further the driving unit is constituted by a frequency generating unit which generates desired frequencies, and the current multiplier circuit constituted by a current mirror circuit.

FIG. 2 is the chart of gained outputs by an LED used in a communication apparatus or system and showing a relation between frequencies [MHz] of inputted signals and relative gains [dB; where a gain at 1 MHz is set zero]. As already known, amplitudes of frequency response outputs of the light emitting device such as the LED are decreasing as frequencies of inputted signal are increased due to a junction capacity of the LED.

A cut-off frequency fc is defined as a frequency having a relative gain of □3 dB to an amplitude of a predetermined lower frequency (in this case 1 MHz). In the LED mentioned above the fc happens to be 48 MHz (see FIG. 2).

The relative gain curve beyond the fc decreases linearly with a gradient of ca.□6 dB/oct due to a time-lag of first order mainly caused by the junction capacity of the LED. In the present embodiment a decreasing feature of the relative gain curve is taken into consideration in order to improve frequency response outputs of the LED.

The above-mentioned feature can be regarded as a feature of a low pass filter. In other words, it is considered that the low pass filter is inserted in a communication path when the LED is employed in a communication system. Consequently, a maximum rate by a baseband digital transmission is determined by a Nyquist frequency equation f_{N}=1/(2 T) so that 96 Mbps is obtained as a maximum bit rate (a transmission rate).

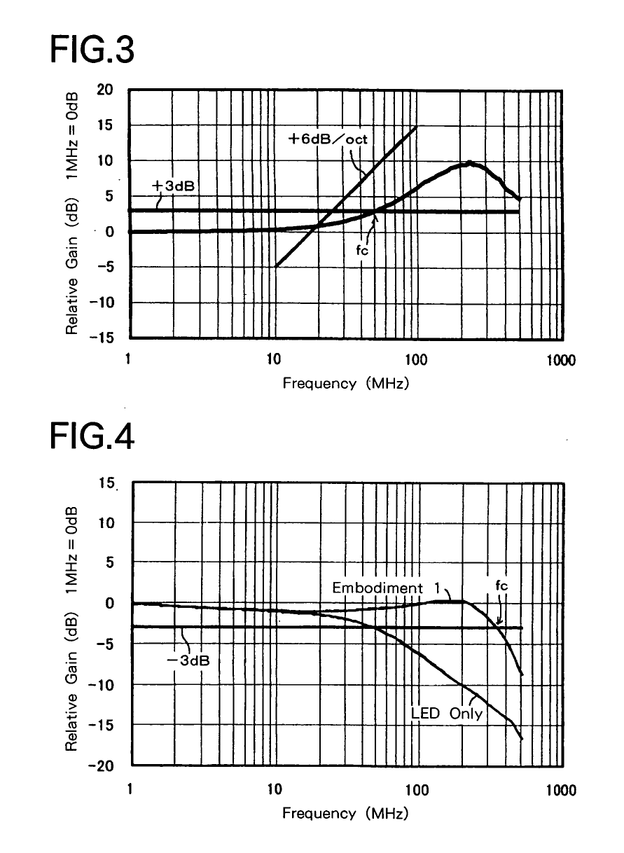

FIG. 3 is the chart showing a frequency response curve of the amplifier by the present embodiment. The frequency response curve of the amplifier basically has a feature characterized by a frequency response curve of a broad band amplifier, but it also has a feature of a high pass filter for cutting lower frequencies having a pole value of the cut-off frequency fc of the LED. However, applicable frequencies to the amplifier have a maximum frequency, so that the maximum frequency is set higher than a cut-off frequency of obtainable light for cutting higher frequencies by arranging a circuit constitution and its components.

FIG. 4 is the chart showing a frequency response curve of gained outputs by the present embodiment. The frequency response curve in FIG. 4 is acquired, when the LED with the frequency response curve shown in FIG. 2 is driven by the amplifier with the frequency response curve shown in FIG. 3.

As being understood by the frequency response curve in FIG. 4, the cut-off frequency fc is raised to a large extent from ca. 50 MHz to 340 MHz. As a result, an optical transmission apparatus having a rate of over 500 Mbps can be realized by employing the LED.

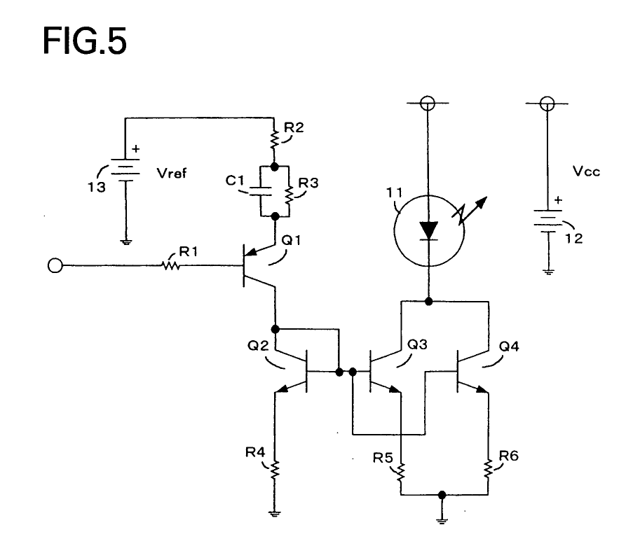

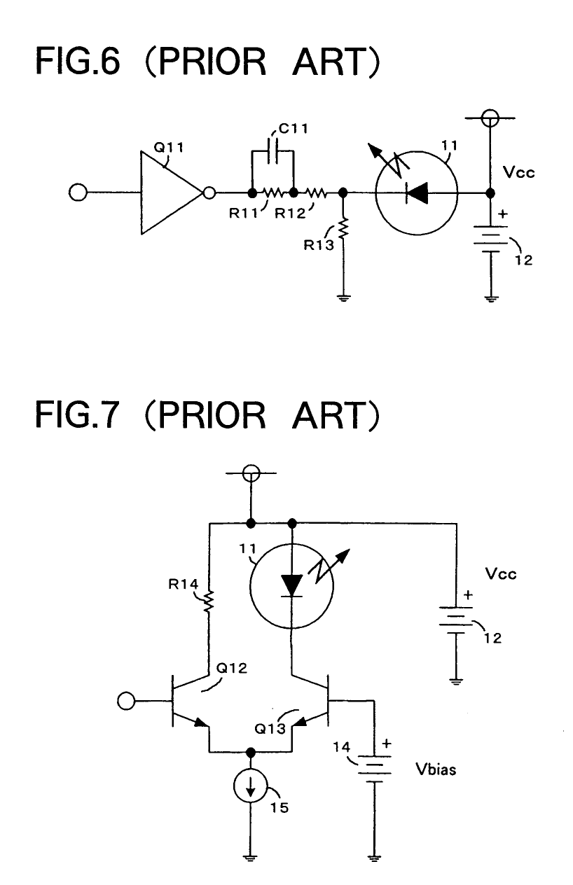

FIG. 5 shows the constitution of the driving circuit of the LED by the present embodiment. In this drawing the same reference characters as in FIGS. 6 and 7 are assigned to the same components. A reference numeral “13” is a reference power source with a voltage of Vref.

Input signals are applied to a base of a transistor Q1 via a resistance R1. The present embodiment is designed so as to employ the so-called digital signals (pulse train) as a signal waveform, but signals employing a sine waveform as a sub-carrier can be also employable without difficulties.

An equivalent circuit to the amplifier 1 in FIG. 1 constituted by the transistor Q1, resistances R1, R2 and R3 and a capacitor C1 is designed to transform a voltage into a current and at the same time to attain required frequency response characteristics.

Transistors Q2, Q3 and Q4 constitute a current mirror circuit corresponding to the current multiplier circuit 2 in FIG. 1. Currents with the same waveform as that of a current flowing in the transistor Q2, flow in the transistors Q3 and Q4 so that a gained current by accumulating currents in these transistors flows out of an LED 11 corresponding to the light emitting device 3 shown in FIG. 1.

Thus since a current intensity with an integer times of the inputted current intensity is obtained by the current mirror circuit, the applying current intensity to the above-mentioned voltage-current transforming circuit (amplifier) is merely 1/(the integer numeral) times of the current intensity flowing out of the LED 11. Consequently, power consumption by the driving circuit can be reduced. And transistors with a low rated current such as a PNP transistor, which is said to be difficult to obtain of good performance, can be selected for the driving circuit, as a result, the driving circuit can be manufactured at a low cost.

In the present embodiment only two transistors are employed in the secondary side of the current mirror circuit, but the number of transistors in the secondary side can be increased without any problems, if necessary.

Resistances R4, R5 and R6 are connected to respective emitters of the transistors Q2, Q3 and Q4 so as to compensate a dispersion among performances of these transistors. If a monolithic IC, which has a negligible dispersion among performances of transistors, is employed instead of these transistors, these resistances can be omitted. If a transistors is a junction-type, an output stage is attained by the junction-type transistor by modifying its emitter size, so that an output current with any number of times of the inputted current can be obtained (the number is not limited to an integer).

Since the output stage is constituted as the current mirror circuit a constant bias current can be flowed out of the LED 11 without difficulties, even when a signal level is at a LOW status.

As explained above, the present embodiment enables an optical communication to obtain signals at higher frequencies than the cut-off frequency of the LED 11 and to attain faster optical communication with a simple arrangement and low power consumption.

The light emitting device driving circuit having a higher transmission rate than the cut-off frequency fc of the light emitting device such as LED 11 or the like, is realized by the present embodiment. For example, the present embodiment enables an LED having a lower cut-off frequency fc than 100 MHz to realize a driving circuit for a fast network interface such as S400 stipulated by IEEE1394. A signal transmission rate by S400 is 500 Mbps (1 bit=2 ns).

As explained above, the present embodiment has the effect of enabling the optical communication to obtain signals at higher frequencies than the cut-off frequency of the light emitting device and to attain faster optical communication with the simple arrangement and low power consumption

In embodiment 1 shown in FIG. 5, the frequency response curve of the driving current for the LED 11 as the light emitting device and the frequency response curve of the emitted light show opposite properties (gradients) each other. The amplifier is constituted by the transistor Q1 having the opposite property to that of the light emitting device, the resistances R1 to R3 and the capacitor C1. A current generated by the amplifier is doubled by the current mirror circuit constituted by the transistors Q2 to Q4. And the doubled current drives the LED 11.

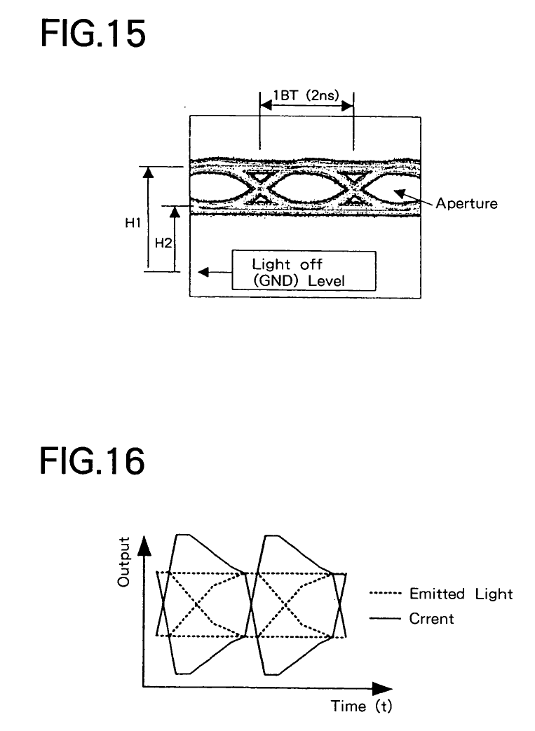

FIG. 15 is the chart showing the eye pattern acquired by the above-mentioned driving circuit. The eye pattern is formed by repeated displayed outputs of synchronized waveforms between two bits, when random digital inputs are added to input signals. The eye pattern is widely employed for evaluating a performance of a digital transmission system. The eye pattern shown in FIG. 15 is the displayed outputs with a frequency of 500 Mbps (1 bit=2 ns).

In the eye pattern in FIG. 15, a minimum pulse width of the digital signal is called 1 BT (1 bit time). Transmission quality is judged by a size of an aperture displayed with a time span of 1 BT. It is easier to judge a level and a timing during a period of demodulating inputted signals, when the larger aperture is acquired. In this case the transmission system is judged as a better system.

Output levels H1 and H2 in FIG. 15 are output levels of emitted light respectively obtained by H level (high level) and L level (low level) of inputted digital signals.

The driving current waveform for obtaining the eye pattern as shown in FIG. 15 is illustrated in FIG. 16. A curve shown by a solid line is a waveform of the inputted current and a curve shown by a broken line is a waveform of the obtained emitted light. In the drawing, portions of a pulse with high frequency components, where the current pulse is steeply raised or steeply decreased, are illustrated exaggeratedly.

Sometimes large sized eye patterns cannot be obtained, because of saturation in the amplifier caused by the added direct current components to optical signals from the light emitting device, depending on a performance of a receiver for receiving the optical signals. An extinction ratio (ER) is employed for indicating a performance of the optical signals, which apt to saturate the amplifier.

The extinction ratio is a logarithmic ratio of the H level (H1) to the L level (H2) of the emitted light, expressed in decibel. Namely it is defined by the following equation.

ER=10×log(H1/H2) [dB]

In order to reduce clipping distortions in the waveform of the emitted light caused by a raised extinction ratio, a measure to apply a reversed bias voltage to the light emitting device is proposed (for example Japanese laid open patent Nos. 58-137340 and 64-5078).

However, the following problems still remain unsolved in the light emitting device driving circuit by the above-described embodiment 1.

The eye pattern in FIG. 15 shows the satisfactory shape and communication at the rate of 500 Mbps is judged to be executed without any troubles. However, sometimes it is probable that offset values of the waveform (of the emitted light in FIG. 16), namely, direct current components may cause troubles. The extinction ratio of the eye pattern in FIG. 15 is 2 [dB], which indicates the size of the aperture is not satisfactory.

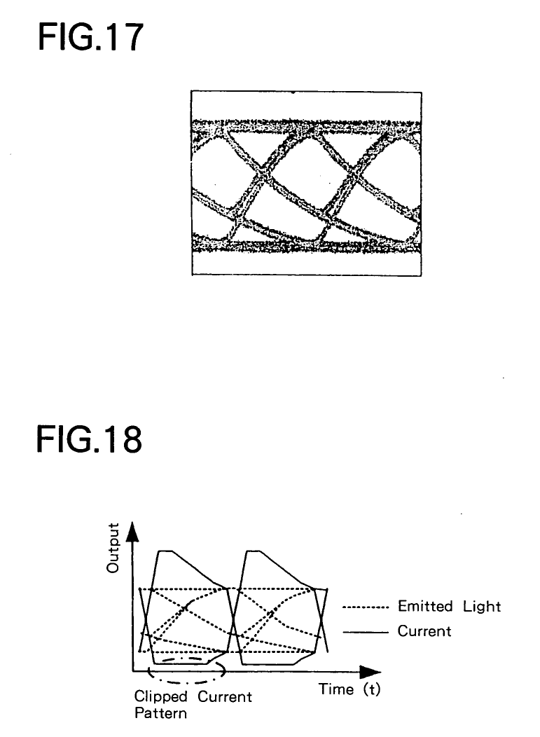

An eye pattern is shown in FIG. 17, when a constant determined by resistance values of R1, R2 and R3 in FIG. 5 is adjusted so as to raise the extinction ratio by reducing direct current components. However, when compared with eye pattern in FIG. 15, the shape of the eye pattern in FIG. 17 is deteriorated such that double lines are observed near the H2 level and flat portions are not observed.

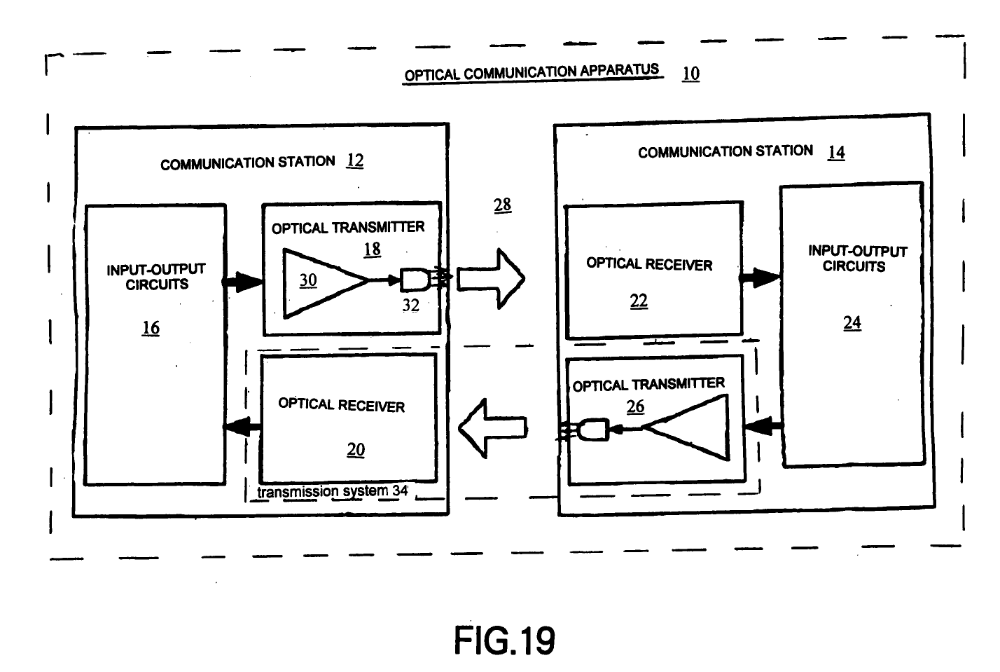

As described above, the following unsolved problem remains in the driving circuit by embodiment 1: a satisfactory eye pattern is not obtained even when the extinction ratio is set larger. It is because that the current mirror circuit does not function at the H2 level (the current waveform is clipped) as shown in FIG. 18 due to reduced the amplitude of the direct current components for improving the extinction ratio.

Output values of the emitted light less than the H2 level in FIG. 15 are outputs which do not carry any transmission information, but it is a required output level for a light emitting device of an optical communication system. As a result, it is difficult to reduce power consumption of the driving circuit further.

An operating status in the driving circuit during a period when the light emitting device is off, is a point to be considered, when the extinction ratio of the light emitting device is raised. As mentioned above, it is a Well known fact that a measure to apply the a reversed bias voltage to the light emitting device is an effective way for attaining a rapid response of the light emitting device when the light emitting device is off.

Embodiments described hereinafter can attain applying methods of the reversed bias current to the light emitting device by a simple way without sacrificing a circuit integration by ICs in view of the feature characterized that the output stage of the current mirror circuit employed in embodiment 1, has a high impedance value during a period of a low output current.

### Embodiment 2

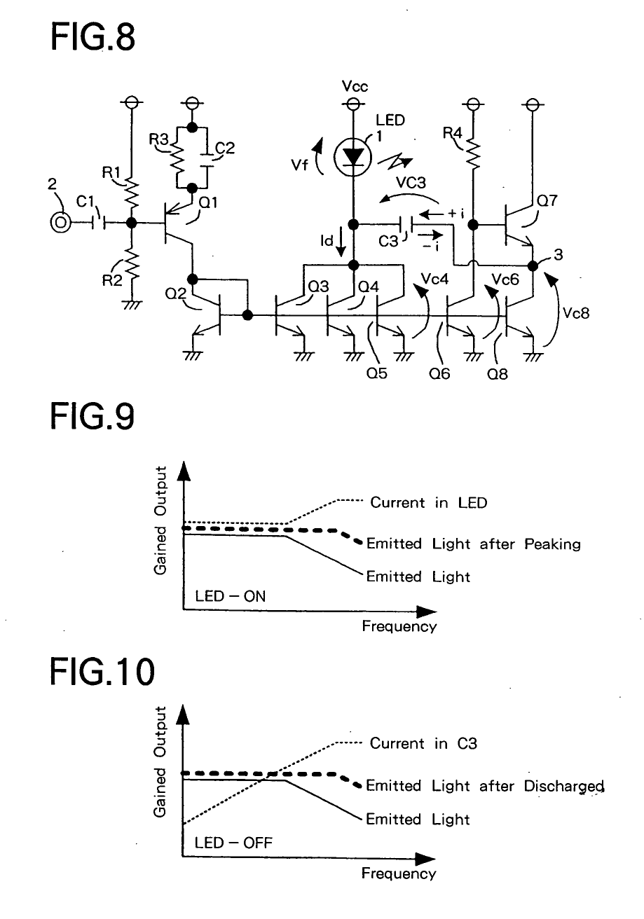

FIG. 8 is the circuit diagram showing the constitution of the driving circuit by embodiment 2, where a feature of the driving circuit for an LED 1 is illustrated in the same way as shown in FIG. 5. In the drawing, a reference numeral “2” is an input terminal of driving signals, a reference numeral “3” is an added current output terminal, reference characters “C1” to “C3” are capacitors, reference characters “R1” to “R4” are resistances and reference characters “Q1” to “Q8” are transistors.

FIG. 9 is the chart showing frequency response curves when the LED is on. In the chart a frequency response curve of the current in LED 1, a frequency response curve of the emitted light from the LED 1 and a frequency response curve of the emitted light after the peaking treatment (which will be explained below), are depicted. FIG. 10 is the chart showing frequency response curves when the LED is off. In the chart a frequency response curve of the capacitor C3, a frequency response curve of the emitted light from the LED 1 and a frequency response curve of the emitted light after a discharge treatment (which will be explained below) are depicted.

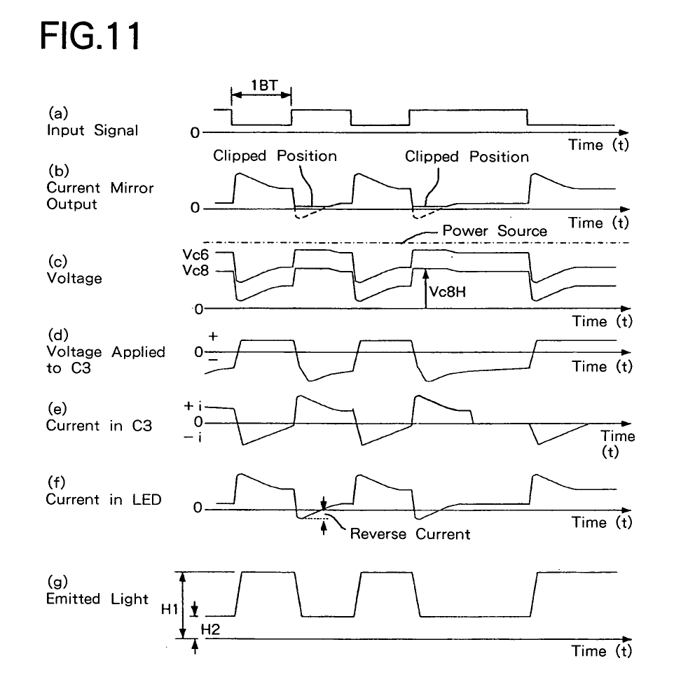

Hereinafter, operating functions of the driving circuit shown in FIG. 8, are explained as referring to (a) to (g) in FIG. 11.

(1) Peaking current waveform generating part

An inputted digital signal (driving signal) having a waveform as shown FIG. 11 (a), is converted to required current amplitude by the transistor Q1. The current bias (direct current component) and a frequency dependent current component gained by the capacitor C2 and resistance R3 are added to the converted current. Here the capacitor C1 functions as a coupling capacitor, which separates the inputted signal from the bias voltage in the transistor Q1 functioning as the amplifier. The resistances R1 and R2 function as voltage dividing resistances which determine a bias voltage applied to a base of the transistor Q1. Together with the resistance R3, the resistances R1 and R2 also determine the direct current component supplied to the transistor Q2.

The driving current is overlaid with a differential component of the driving current by the capacitor C2 and the resistance R3 so that a frequency dependent driving current waveform is determined (this procedure is called a peaking treatment). A relation among the cut-off frequency fc of the LED 1 used as the light emitting device, a capacitance C of the capacitor C3 and a resistance value R of the resistance R3 is roughly expressed by the following equation.

fc=1/(2π×C×R)

(2) Current mirror part

Transistor Q2 and transistors Q3 to Q5 constitute a current mirror circuit so that a current flowing in the corrector of the transistor Q2 is tripled and outputted as the driving current so as to drive the LED 1. A waveform of an outputted current Id is illustrated in FIG. 11(b). Clipped portions are observed in a low current region of the current waveform.

(3) Current distributors

The transistors Q2 and Q6 constitute a current mirror circuit functioning as a distributor, where the inputted current to the transistor Q2 is outputted from the transistor Q6. In the same manner, the transistors Q2 and Q8 constitute a current mirror circuit functioning as other distributor, where the inputted current to the transistor Q2 is outputted from the transistor Q8.

(4) Current-voltage conversion part

The outputted current from the current mirror circuit constituted by transistors Q2 and Q6 (a corrector current of the transistor Q6) has the same phase as the above-mentioned current Id and an outputted voltage is dropped by a resistance R4. As shown in FIGS. 11(c) and (g), a corrector voltage Vc6 of the transistor Q6 is low when the emitted light level is high (H1) and Vc6 is high when the emitted light level is low (H2).

In other words, the current mirror circuit constituted by transistors Q2 and Q6 functions as a current-voltage converter. Here a resistance value of the R4 is set as high as possible so that a larger voltage change can be obtained by the corrector current of the transistor Q6.

A transistor Q7 functions as an emitter follower. A lower voltage by Vbe than a base voltage of the transistor Q7 is obtained with a low impedance at the terminal 3 (see Vc8 in FIG. 11(c)) between the base of the transistor Q8 and the emitter of the transistor Q7.

(5) Discharge circuit

A current with the same phase as the current Id, flows in the corrector of the transistor Q8 as flowing in the transistor Q6. Since the flowing current to the corrector of the transistor Q8 is the outputted current of the current mirror circuit, it functions as a constant current source, which varies in accordance with the inputted signal. A sink current value when the emitted light level is H1 is larger than a sink current value when the emitted light level is H2.

In other words when the emitted light level is H1 a larger portion of the current sinks into the transistor Q8 so that the corrector voltage Vc8 is lowered (an impedance value between the corrector and the emitter of the transistor Q8 is low). At this stage the output voltage of the transistor Q7 is low so that it effects to the corrector voltage Vc8 in the same direction as the current which sinks into the transistor Q8. When the emitted light level is H2 a smaller portion of the current sinks into the transistor Q8 so that the corrector voltage Vc8 is not lowered too much (an impedance value between the corrector and the emitter of the transistor Q8 is high).

While the output of the transistor Q7 is at the high voltage side, the voltage Vc8 is raised. By combining the above-mentioned (4) current-voltage conversion part and (5) discharge circuit, when the emitted light level is H1, the low impedance voltage is supplied with a reversed phase to that of the emitted light, and when the emitted light level is H2 the high impedance voltage is supplied.

In the present embodiment, the driving circuit has the reverse frequency response curve to the frequency response curve of the LED 1 functioning as the light emitting device. The driving circuit is arranged as a current output type amplifier constituted by transistors Q1 to Q8, having a frequency response curve increasing from the cut-off frequency of the LED 1 with a predetermined gradient. The current output type amplifier has a frequency generating part constituted by the transistor Q1, the capacitor C2 and the resistance R3, a current multiplier part including two current mirror circuits constituted by the transistors Q2 to Q6 and the discharge circuit constituted by the transistors Q7 and Q8 for supplying the reverse current distributed current from the current multiplier part, to the LED1.

The above-mentioned discharge circuit has the terminal 3 for outputting the distributed current and the capacitor C3 connected between the terminal 3 and a cathode of the LED 1. A power source Vcc having fluctuations in its voltage or impedance, synchronized with the driving current Id for the LED 1.

As mentioned above the capacitor C3 is connected between the terminal 3 for outputting the corrector current of the transistor Q8 and the cathode of the LED 1 as the light emitting device. If the capacitor C3 is omitted, the cathode voltage Vc4 of the LED 1 indicates an almost constant voltage lower by a forward voltage drop Vf of the LED 1 than the power source voltage Vcc. The cathode voltage Vc4 fluctuates a little, even when the emitted light level is changed from H1 to H2. In other words, from the high frequency viewpoint, the cathode voltage Vc4 of the LED 1 is positioned nearer to a virtual ground side than the capacitor C3 so that the voltage hardly changes due to the constant low impedance state.

Hereinafter a voltage VC3 applied to the capacitor C3 and a current flowing in the capacitor C3 (see FIG. 11(e)) are explained.

When the emitted light level is H1, a voltage of (the power source voltage−Vf) is applied to the LED 1 and a low voltage is applied to the opposite side (the corrector side of the transistor Q8). In this state, the capacitor C3 is charged by a voltage difference between two voltages (the voltage VC3 is at a plus side in FIG. 11(d)).

When the emitted light level is H2, the corrector voltage of the transistor Q8 is rapidly raised to Vc8H. In this state, since the charged voltage of the capacitor is not changed, the voltage of the capacitor at the LED 1 side is also rapidly raised. Consequently, a voltage of [Vc8H+(power source voltage−Vf)] is generated at the cathode of the LED 1, so that a current flows in the LED 1 in a reverse direction i.e. in a minus direction (see FIG. 11(f).

In the present embodiment, since an PN junction diode is supposed to be employed as the LED 1, the reverse current flowing to the PN junction facilitates extinguishing internal carries (discharging internal electric charges in the LED 1) which are contributing to the light emission. In other words, the PN junction LED can attain reducing the rise time of the light emission.

As shown in FIG. 11(e), edges in a current response curve of the capacitor C3 are emphasized and a frequency response curve of the current in the capacitor C3 is set as shown in FIG. 10. (If a capacity of the capacitor is too large, a gain pole of the current shifts to a lower frequency side so that a required eye pattern cannot be obtained.)

As mentioned above, when the extinction ratio is set larger, the frequency response of the driving current determined by the capacitor C2 is effective when the light emission is started, but the frequency response does not function when the light emission is stopped due to the clipped driving current Id of the LED 1.

However, the above-mentioned problem is solved by flowing a current to the capacitor C3 as in the present embodiment, since the differential current is added to the driving current for LED 1 when the light emission is stopped (emitted light level is H2).

In other words, when the light emission is started, the peaking treatment can be performed by the capacitor C2 and when the light emission is stopped, the peaking treatment can be performed by the capacitor C3. This is very effective when a light emitting device having different characteristics in starting and stopping the light emission, which means precise adjustments can be made by setting constant determined by capacitors C2 and C3 so that this feature is particularly very effective to optical communication apparatuses.

The charged electric charge in the capacitor C3 is partly used for extinguishing the internal carriers in the LED 1 and remaining portion of the electric charge is absorbed by the correctors of the transistors Q3 to Q5 and discharged therefrom.

When the emitted light level is H1, the corrector current of the transistor Q8 is raised rapidly due to the peaking effect by the capacitor C2. On the other hand the corrector voltage of the transistor Q6, namely, the emitter voltage of the transistor Q7 electrically connected to the transistor Q6 via an emitter-corrector linkage, is decreased rapidly.

In other words, the voltage at the transistor Q8 side of the capacitor C3 is rapidly lowered and the capacitor C3 is started to be charged by the constant current source of the transistor Q8. Since the charging current has the same phase and same frequency response property as the current Id and the capacitor C3 is virtually shorted from the high frequency viewpoint, the current Id is increased in proportion to a current intensity to the corrector of the transistor Q8.

A rising response of the light emission of the LED 1 is improved a little bit by inserting a path constituted by the capacitor C3. Therefore, the extinction ratio is enhanced and power consumption of the driving circuit can be reduced by a simple method.

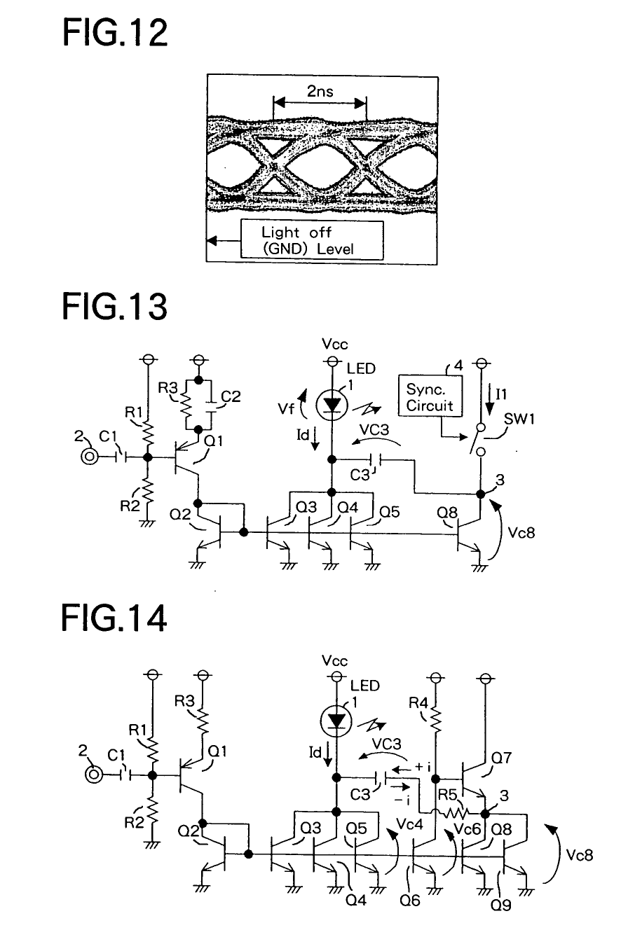

FIG. 12 is the chart showing the eye pattern of the LED 1 with a bit rate of 500 Mbps obtained by the present embodiment. An LED having the cut-off frequency fc of 85 MHz is employed as the LED 1. The obtained extinction ratio is 5 dB and the eye pattern shows satisfactorily wide apertures.

A smaller light emitting unit with low power consumption for an optical communication apparatus, can be realized for an optical receiver which does not require a high extinction ratio, as the same optical amplitude being kept. In addition, the present embodiment can improve the rising response of the light emission through the current peaking circuit constituted by the capacitor C2 and the resistance R3 and setting response of the light emission through the discharge circuit constituted by the capacitor C3.

Thus, the rising response and setting response of the light emission can be adjusted separately. For example, a light emitting device having different properties in its rising response and setting response can be adjusted separately so that eye pattern properties of the emitting device can be improved more.

In the present embodiment, the current mirror circuits are utilized in various ways so as to keep the number of parts at a minimum level, which can suppress the size of the driving circuit to a certain scale.

### Embodiment 3

FIG. 13 is the circuit diagram showing the constitution of the driving circuit for the LED by embodiment 3 of the present invention. In the drawing the same reference character as in FIG. 5 refers the same component.

In the present embodiment the signal with the same phase as the current Id and the reverse current is applied to the LED 1 at the time when it is off in the same manner as in embodiment 2. A different feature from embodiment 2 is that a switch SW1 turned on/off by a synchronous circuit 4 is connected to the corrector of the transistor Q8.

Inputting signals to the synchronous circuit 4 can be sampled from inputting signals of the whole system (not shown in the drawing) or a part of the system. A transistor, an FET or the like can be employed as the switch SW1.

In the present embodiment, the power source for the whole circuit is utilized as a power source with low impedance for raising a voltage applied to the capacitor C3, which stores electric charge for a reverse bias current. When the emitted light level is H1, only the corrector voltage of the transistor Q8 can lower the voltage at a terminal of the capacitor C3 connected to the transistor Q8. Consequently, a capacity of the capacitor C3 is determined such that enough electric charge for the reverse bias current can be charged by the corrector current of the transistor Q8 during the minimum pulse time, 1 BT.

### Embodiment 4

FIG. 14 is the circuit diagram showing the constitution of the driving circuit of the LED by embodiment 4 of the present invention. In the drawing the same reference character as in FIG. 5 refers the same component.

In the present embodiment, the frequency response of the LED 1 as the light emitting device is improved only by the discharge circuit. In other words, a transistor Q9 is added in parallel to the transistor Q8 so as to enhance a charging ability of the capacitor C3, namely, so as to raise a differential forward current to the LED 1. While the capacitor C2 for the peaking treatment employed in the embodiment 2 is eliminated.

In the circuit illustrated in FIG. 14, differential currents in both forward and reverse directions are applied to the LED 1. The applied current intensity in the reverse direction to the LED 1 is the same intensity as in embodiment 2. Here a current waveform is converted into a voltage by the resistance 4, and the transistor Q7 constitutes a buffer amplifier.

The following features of the present embodiment are different from embodiment 2. The transistor Q9 is connected in parallel to the transistor Q8 functioning as the current source for the current mirror circuit so as to lower a difference in two impedance, one is impedance between the emitter of the transistor Q7 and the corrector of the transistors Q8, and other is impedance between the emitter of the transistor Q7 and the corrector of the transistor Q9. Thus the time constant of the capacitor C3 during charging and discharging can be adjusted.

The resistance R4, the capacitor C3 and a resistance R5 adjust a differential current intensity. In order to raise an employable frequency limit of the LED 1, a voltage amplitude applied to the capacitor is adjusted by the resistance R4. In this case, a cut-off frequency fc is determined in the following equation, when a capacitance of the capacitor C3 is designated as C and a resistance value of the resistance R4 is designated as R.

fc=1/(2π×C×R).

Consequently, differential currents with symmetrical waveforms in forward and reverse directions flow in the LED 1 used as the light emitting device. Here frequency response curve of the LED 1 in both cases when the LED 1 is on and off, show the same pattern as illustrated in a thick broken line in FIG. 10. Thus, the same effects as in the previous embodiments can be attained in the present embodiment.

The present invention relating to the driving circuit for the light emitting device employed in the optical communication apparatus, are widely applicable to systems where optical signals with higher frequencies than the cutoff frequency of the light emitting device.

As explained above, the present invention attains the following effects. The extinction ratio is raised by the simple method and at the same time the power consumption in apparatuses which employ the light emitting device by the present invention, is lowered, as keeping the high frequency optical waveform more enhanced than the original frequency response curve of the light emitting device.

What is claimed is:

1. A driving circuit for a light emitting device, wherein:
said driving circuit has a driving unit having a frequency response curve indicating opposite property to a frequency response curve of said light emitting device.

2. The driving circuit for said light emitting device according to claim 1, wherein:
said driving unit comprises a power outputting type amplifier having a gain curve increasing with a gradient of ca. 6 dB/oct starting from a cut-off frequency of said light emitting device.

3. The driving circuit for said light emitting device according to claim 2, wherein:
said amplifier comprises a frequency generating unit for generating a desired frequency and a current multiplier unit constituted by a current mirror circuit.

4. A driving method for driving a light emitting device, wherein:
said light emitting device is driven by a driving unit having a frequency response curve indicating opposite property to a frequency response curve of said light emitting device.

5. The driving method for driving said light emitting device according to claim 4 wherein:
said light emitting device is driven by said driving unit comprises a power outputting type amplifier having a gain curve increasing with a gradient of ca. 6 dB/oct starting from a cut-off frequency of said light emitting device.

6. The driving circuit for said light emitting device according to claim 1, wherein:
said driving unit comprises a power outputting type amplifier having a gain curve increasing with a predetermined gradient starting from a cut-off frequency of said light emitting device, wherein:
said amplifier comprises:
a frequency generating unit for generating a desired frequency;
a current multiplier unit constituted by a current mirror circuit; and
a discharge circuit for applying a reverse current distributed from said current multiplier unit to said light emitting device.

7. The driving circuit for said light emitting device according to claim 6, wherein:
said discharge circuit has a capacitor connected between a terminal for outputting the distributed current from said current multiplier circuit and said light emitting device, wherein:
a voltage source having fluctuations in its voltage change or impedance synchronized with a driving current of said light emitting, is connected to said terminal for outputting the distributed current.

8. The driving method for said light emitting device according to claim 4, wherein:
driving said light emitting device by said driving unit comprising:
a frequency generating unit having a gain curve increasing with a predetermined gradient starting from a cut-off frequency of said light emitting device and
a power outputting type amplifier having current multiplier unit constituted by a current mirror circuit; and
distributing a reverse current from said current multiplier unit to said light emitting device by a discharge circuit.

9. The driving method for said light emitting device according to claim 8, wherein:
said discharge circuit has a capacitor connected between a terminal for outputting the distributed current from said current multiplier circuit and said light emitting device, wherein:
a reverse current is applied to said light emitting device from said capacitor.

10. An optical communication apparatus equipped with a driving circuit for a light emitting device specified in either one of claims 1, 2, 3, 6 or 7.
